(19) United States
(12) Patent Application Publication
(10) Pub. No.: US 2007/0103235 A1
(43) Pub. Date: May 10, 2007

(54) Inductorless broadband RF low noise amplifier

(75) Inventor: Joseph P. Heck, Fort Lauderdale, FL (US)

Correspondence Address: CUENOT & FORSYTHE, L.L.C., 12230 FOREST HILL BLVD., SUITE 120, WELLINGTON, FL, 33414, US

(73) Assignee: Motorola, Inc.

(21) Appl. No.: 11/267,109

(22) Filed: Nov. 4, 2005

(51) Int. Cl. H03F 3/45

(52) U.S. Cl. 330/253

(57) ABSTRACT

A wideband low noise RF amplifier (LNA) (100) comprising an inductorless internal amplifier load (102). The load can include a first resistor (104) coupled to an external load or a load isolation stage (150) and a first current source (112) connected in parallel to the first resistor to provide at least a first portion of load current. The load also can include a second resistor (106) coupled to the external load or the load isolation stage and a second current source (114) connected in parallel to the second resistor to provide at least a second portion of load current. The first and second current sources can include metal oxide semiconductor field effect transistors (MOSFETs). A biasing system (136) can be provided to bias the first and second MOSFETs.

### BACKGROUND OF THE INVENTION

1. Field of the Invention

The present invention generally relates to RF amplifiers and, in particular, low noise wideband linear RF amplifiers.

2. Background of the Invention

The gain of a low noise RF amplifier (LNA) typically is proportional to the value of a load impedance presented by an amplifier load internal or external to the LNA. Thus, it is generally desirable to provide an internal amplifier load having high resistance values to achieve high gain. However, the use of such high resistance values results in a relatively large DC voltage drop across the resistors, which tends to limit the dynamic range of the LNA. Accordingly, LNAs for application in a wireless receiver front end normally include inductors in parallel with the resistors. The inductors help to maintain high output impedance at RF frequencies by resonating with any circuit or stray capacitance in the frequency band of interest, and by allowing a relatively high resistive load in the frequency band of interest, while providing relatively low DC resistance. This minimizes the DC voltage drop across the resistors of the output port, thereby improving the dynamic range of the LNA.

Several problems arise from the use of inductors in an LNA, however. For instance, the inductors have limited operational bandwidth within the LNA because they resonate with stray capacitance in the LNA circuit, and must therefore be tuned for each frequency band of operation. Accordingly, to achieve wideband performance in an LNA, a tunable inductance or capacitance, or multiple individually tuned circuits are required. Moreover, RF switches are required to switch between the individual tuned circuits. Such switches tend to degrade the gain, noise and distortion of the LNA, thus significantly degrading the performance of the system.

Inductors increase integrated circuit (IC) die size because they occupy a relatively large area of the die. Integrating the inductors into the IC also increases the complexity of the IC manufacturing process. Moreover, the inductors can electromagnetically couple with other IC components, which can degrade circuit performance. Tuned inductors are not practically realizable in IC manufacturing processes, and while tuned capacitances can be achieved with varactors or other voltage variable capacitors, these tuned capacitors have significant limitations in the realizable percentage change of capacitance and can also seriously degrade the linearity of the amplifier, thus degrading the intermodulation distortion performance.

### SUMMARY OF THE INVENTION

The present invention relates to a wideband low noise RF amplifier (LNA) including an inductorless internal amplifier load (hereinafter “load”). The load can include a first resistor coupled to an external load or a load isolation stage and a first current source connected in parallel to the first resistor to provide at least a first portion of load current. The load also can include a second resistor coupled to the external load or the load isolation stage and a second current source connected in parallel to the second resistor to provide at least a second portion of load current. The LNA can include a differential balanced line input. The first portion of the LNA load current can be generated on a first line of the balanced line and the second portion of load current can be generated on a second line of the balanced line.

The first current source can include a first metal oxide semiconductor field effect transistor (MOSFET) and the second current source can include a second MOSFET. A drain of the first MOSFET can be connected to a first terminal of the first resistor, a source of the first MOSFET can be connected to a second terminal of the first resistor; a drain of the second MOSFET can be connected to a first terminal of the second resistor, and a source of the second MOSFET can be connected to a second terminal of the second resistor. In addition, a gate of the first MOSFET can be connected to a gate of the second MOSFET.

The wideband LNA further can include a biasing system that biases the first and second MOSFETs. The biasing system can include a third resistor having a first terminal connected to a gate of the first MOSFET and the third resistor having a second terminal connected to a drain of the first MOSFET, and a fourth resistor having a first terminal electrically connected to a gate of the second MOSFET and the fourth resistor having a second terminal connected to a drain of the second MOSFET.

The wideband LNA also can include a load isolation stage that isolates the internal amplifier load from an external load. The load isolation stage can include a first load isolation device and a second load isolation device. The first and second load isolation devices also can be MOSFETs. A gate of the first load isolation device can be connected to a first terminal of the first resistor, and a gate of the second load isolation device can be connected to a first terminal of the second resistor.

The wideband LNA also can include a first cascode device connected to the first resistor and a second cascode device connected to the second resistor. The first and second cascode devices can be MOSFETs. A first automatic gain control (AGC) device can be connected to the first cascode device and a second AGC device can be connected to the second cascode device. The first and second AGC devices also can be MOSFETs.

A capacitor can be connected between a source of the first cascode device and a source of the second cascode device. The capacitor, the first cascode device, and the second cascode device can form a differential amplifier. The differential amplifier can provide positive feedback for RF signals processed by the LNA.

The internal amplifier load further can further include a third current source connected to the first current source to provide a third portion of current and a fourth current source connected to the second current source to provide a fourth portion of current. The third portion of current can be generated on the first line and the fourth portion of current can be generated on the second line. The third current source can include a third MOSFET and the fourth current source includes a fourth MOSFET.

### BRIEF DESCRIPTION OF THE DRAWINGS

Preferred embodiments of the present invention will be described below in more detail, with reference to the accompanying drawings, in which:

FIG. 1 is a schematic diagram of a circuit that is useful for understanding the present invention.

FIG. 2 is a graph of voltage gain and noise figure of an LNA that is useful for understanding the present invention.

FIG. 3 is a Smith Chart of input impedance of an LNA that is useful for understanding the present invention.

FIG. 4 is another graph of input impedance return loss of an LNA that is useful for understanding the present invention.

FIG. 5 is a schematic diagram of another circuit that is useful for understanding the present invention.

### DETAILED DESCRIPTION

While the specification concludes with claims defining the features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

The present invention relates to a radio frequency (RF) low noise amplifier (LNA) having a high impedance internal amplifier load, while controlling the DC voltage drop across the load without the use of inductors. Accordingly, the LNA of the present invention provides exceptional dynamic range and a linear frequency response over a broad frequency range. In addition, the wideband performance of the invention allows for the use of several LNA inputs without requiring switches to select between multiple narrow band tuned circuits, thus minimizing circuit noise.

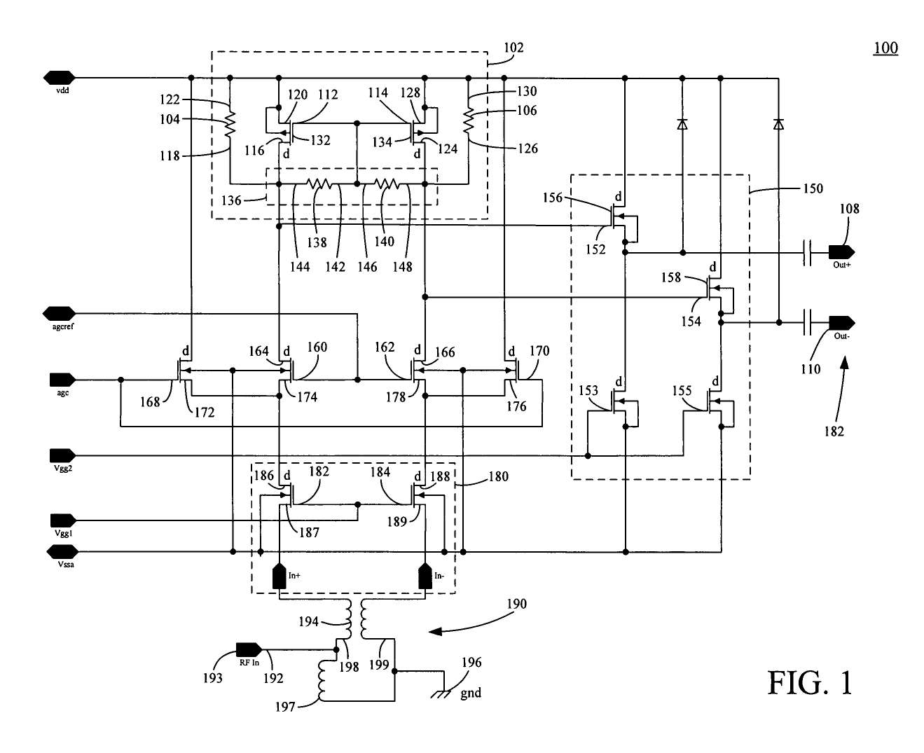

FIG. 1 is a schematic diagram of an LNA 100 that is useful for understanding the present invention. The LNA 100 can be implemented on a single integrated circuit (IC) chip, thus minimizing manufacturing costs and system dimensions. Moreover, the LNA 100 can be implemented in a differential balanced configuration as shown in FIG. 1, which advantageously provides exceptional signal isolation between the input stage 190 and output 182 of the LNA 100.

The LNA 100 includes an inductorless internal amplifier load (hereinafter “load”) 102. The load 102 can include a first resistor 104 and a second resistor 106. The first and second resistors 104, 106 can be coupled to a load external to the LNA 100 via output terminals 108, 110. In an arrangement in which the LNA 100 is formed on an IC chip, the external load can be formed on the IC chip on which the LNA 100 is formed, or can be external to the IC chip containing the LNA 100.

A first current source 112 can be connected in parallel to the first resistor 104 and a second current source 114 can be connected in parallel to the second resistor 106. The current sources 112, 114 can provide a significant portion of load current generated by the load 102, thus enabling the load resistors 104, 106 to have relatively high values of resistance, while minimizing the voltage drop across the resistors 104, 106. Accordingly, the LNA 100 can be implemented with high gain without sacrificing dynamic range. For instance, the load resistors 104, 106 can have resistance values greater than 1.5 k Ohms to provide a voltage gain greater than 25 dB when used with an input stage which has a transconductance gain of 20 mS, while maintaining a third order intermodulation input intercept point (IIP3) greater than −7 dBm over a frequency range of 100 MHz to 2.5 GHz.

Since the load 102 does not include inductors, which tend to resonate with stray circuit capacitance, high gain and high dynamic range can be provided over a broad frequency range. Indeed, the absence of load inductors can enable the LNA 100 to operate on multiple frequency bands without the need for RF switching or tuning inductance or capacitance on the load of the LNA 100.

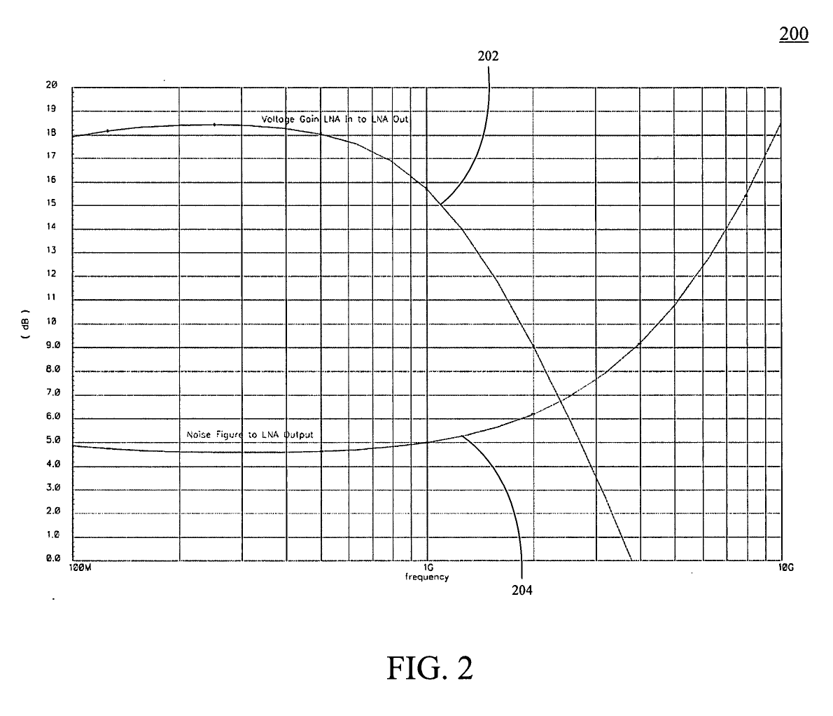

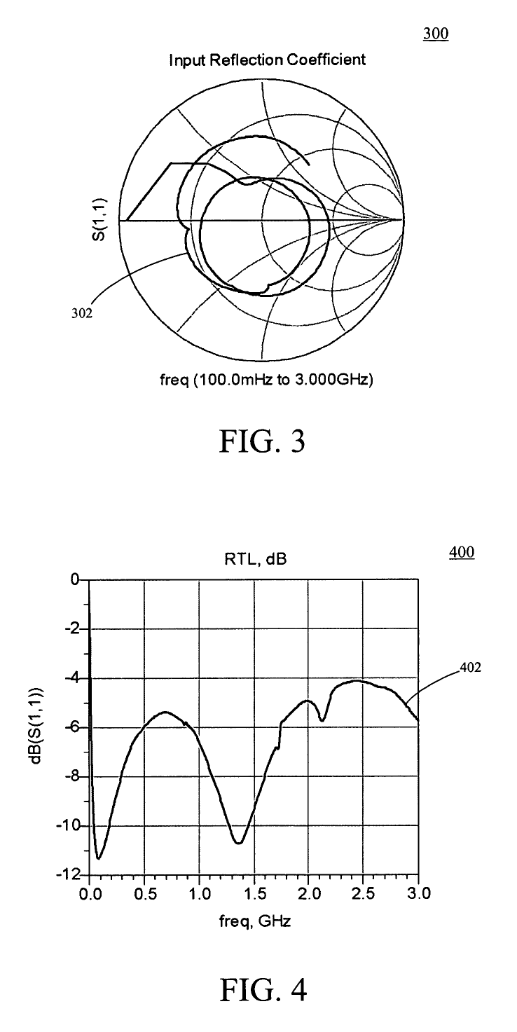

Briefly referring to FIG. 2, a graph 200 of simulated performance of the LNA 100 is shown. In particular, the graph 200 shows a plot 202 of the anticipated voltage gain vs. frequency that can be achieved by the LNA 100. In addition, the graph 200 also shows a plot 204 of the anticipated noise figure vs. frequency of the LNA 100. FIG. 3 presents a Smith Chart 300 that shows a plot 302 of the simulated input impedance reflection coefficient for the LNA 100, and FIG. 4 presents a graph 400 that shows a plot 402 of the simulated input impedance return loss vs. frequency of the LNA 100.

Referring again to FIG. 1, the first and second current sources 112, 114 can comprise metal oxide semiconductor field effect transistors (MOSFETs). MOSFETs can be configured to have high output impedance, thus helping to maintain a high gain for the LNA 100 over a wide frequency range. In this particular arrangement, a drain 116 of the first current source 112 can be connected to a first terminal 118 of the first resistor 104 and a source 120 of the first current source 112 can be connected to a second terminal 122 of the first resistor 104. Similarly, a drain 124 of the second current source 114 can be connected to a first terminal 126 of the second resistor 106 and a source 128 of the second current source 114 can be connected to a second terminal 130 of the second resistor 106. Further, a gate 132 of the first current source 112 can be connected to a gate 134 of the second current source 114. Still, the invention is not limited to the use of MOSFETs as the first and second current sources 112, 114 and other types of current sources can be used, such as PNP bipolar junction transistors.

The LNA 100 also can include a biasing 136 system that biases the first and second current sources 112, 114. The biasing system can include a third resistor 138 and a fourth resistor 140. The third resistor 138 can have a first terminal 142 connected to the gate 132 of the first current source 112, and the third resistor 138 having a second terminal 144 connected to the drain 116 of the first current source 112. Likewise, the fourth resistor 140 can have a first terminal 146 connected to the gate 134 of the second current source 114 and a second terminal 148 connected to the drain 124 of the second current source 114. The values of the third resistor 138 and the fourth resistor 140 can be higher than the values of the first and second resistors 104, 106, thus insuring that the large voltage gain achieved by the use of the first and second resistors 104, 106 is not degraded. For example, the values of the third and fourth resistors 138, 140 can be at least five to ten times greater than the values of the first and second resistors 104, 106. This bias arrangement provided by resistors 104 and 106 automatically biases the gate voltages of the current source transistors 112 and 114 to provide the correct amount of bias current. This arrangement also keeps the source to drain voltages of the current source transistors 112 and 114 sufficiently high to allow for linear, low distortion operation.

The LNA also can include a load isolation stage 150 that isolates the load 102 from the external load, thus insuring a high level of LNA 100 performance over a wide range of impedance presented by the external load. The load isolation stage 150 can include a first load isolation device 152 and a second load isolation device 154. In one arrangement, the first and second load isolation devices 152, 154 can comprise MOSFETs. In this arrangement, a gate 156 of the first load isolation device 152 can be connected to the first terminal 118 of the first resistor 104, and a gate 158 of the second load isolation device 154 can be connected to the first terminal 126 of the second resistor 106. Isolation devices 152 and 154 are not limited to implementation using MOSFETs, but also can be implemented with NPN bipolar junction transistors, for example.

The LNA 100 also can include a first cascode device 160 connected to the first resistor 104 and a second cascode device 162 connected to the second resistor 106. The cascode devices 160, 162 can deliver current to the load 102 and can be implemented to improve distortion characteristics of the LNA 100. In one arrangement, the cascode devices 160, 162 also can comprise MOSFETs. In such an arrangement, a drain 164 of the first cascode device 160 can be connected to the first terminal 118 of the first resistor 104, and a drain 166 of the second cascode device 162 can be connected to the first terminal 126 of the second resistor. Still, the invention is not limited to the use of MOSFETs in the first and second devices 160, 162; other types of cascode devices can be used. For example, the cascode devices can be implemented with NPN bipolar junction transistors.

In addition, automatic gain control (AGC) devices 168, 170 can be provided. The first AGC device 168 can be connected to the first cascode device 160 and the second AGC device 170 can be connected to the second cascode device 162. For instance, a source 172 of the first AGC device 168 can be connected to a source 174 of the first cascode device 160 and a source 176 of the second AGC device 170 can be connected to a source 178 of the second cascode device 162. The AGC devices 164, 166 can selectively divert current from the cascode devices 160, 162, respectively, to control the gain the LNA 100. Again, MOSFETs can be used in the AGC devices 164, 166, although the invention is not limited in this regard. As is the case for the cascode devices, the AGC devices are not limited to implementation with MOSFETs, but could also be implemented, for example, with NPN bipolar transistors. It can be desirable for the AGC devices 168 and 170 to match the cascode devices 160 and 162 in type and geometry for predictable gain control characteristics.

A differential common gate amplifier stage 180 comprising MOSFET 182 and MOSFET 184 can be provided to receive input signals from the input stage 190. The MOSFETs 182, 184 can provide current mode output from their respective drains 186, 188 to the cascode devices 160, 162. The amplifier stage 180 can have, for example, a transconductance gain of 20 mS, corresponding to an input impedance of 50 Ohms.

The amplifier stage 180 can receive an input signal 192 from the input stage 190. The input stage 190 can include a transformer 194, which can differentially apply the single ended input signal 192 to the respective sources 187, 189 of the MOSFETs 182, 184. In an alternate arrangement, a differential input signal, if available, can be directly applied to the respective sources 187, 189 of the MOSFETs 182, 184. In this case, inductors can be connected from the two differential inputs to ground to provide a DC path for the bias currents of MOSFETs 182 and 184. In addition, coupling capacitors can be used to couple the differential input signals to the sources of MOSFETs 182 and 184.

The input interface 190 also can include an input inductor 197 to provide high impedance at RF frequencies to maintain a voltage potential between the RF input 193 and ground 196, while providing a low DC resistance to ground for the bias current of input device 187. The input interface 190 can also provide a low resistance DC path for the bias current of input device 189 through transformer 194 to its terminal 199 connected to ground 196.

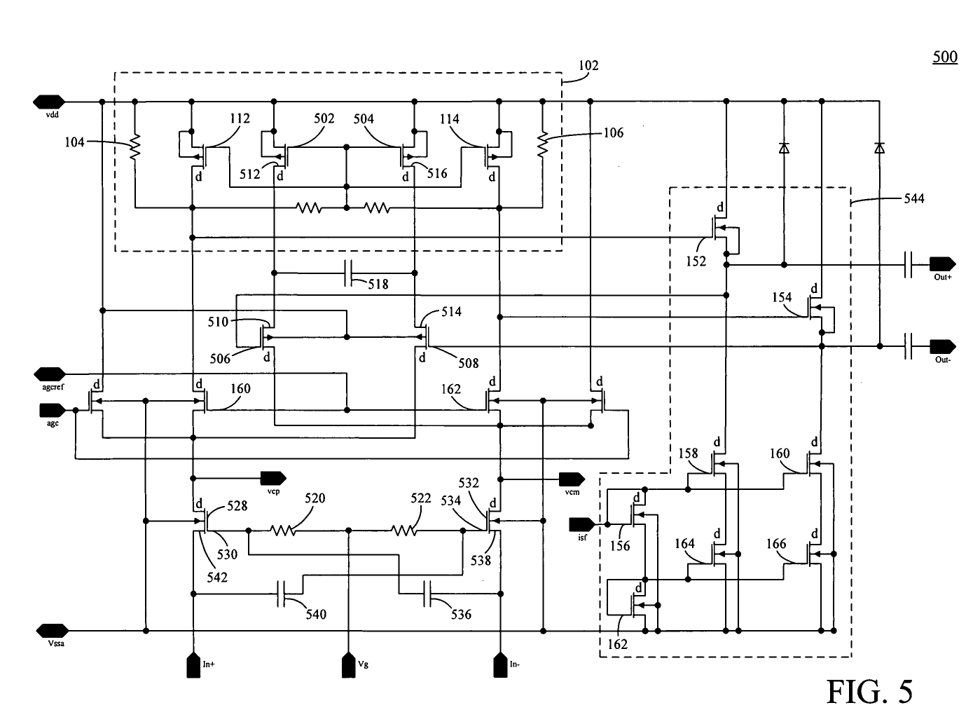

Referring to FIG. 5, a schematic diagram is presented of another LNA 500 useful for understanding the present invention. In addition to the first and second current sources 112, 114, a third current source 502 and a fourth current source 504 can be implemented to generate a portion of the load current provided by the load 102, thus reducing the amount of load current generated by the first and second current sources 112, 114. In addition, a third cascode device 506 and a fourth cascode device 508 also can be provided to carry a portion of the current that otherwise would be carried by cascode devices 160, 162. This circuit topography reduces the DC current needed from current source devices 112 and 114 and enables the load resistors 104, 106 to have higher resistance values, thus providing greater gain for the LNA 500 in comparison to the LNA 100. The reduced DC current in devices 112, 114, 160, and 162 allows these devices to be of smaller geometry. This makes the parasitic capacitance associated with these devices smaller. This smaller parasitic capacitance allows for a greater gain bandwidth product of the amplifier. Thus for a given gain, the bandwidth can be higher by leaving the load resistor values the same, or for a given bandwidth the gain can be higher by increasing the load resistor values. Even though the DC current values in devices 112, 114, 160, and 162 are reduced, the signal currents remain essentially the same in devices 160 and 162 and the load resistors 104 and 106.

In one embodiment, the current sources 502, 504 and the cascode devices 506, 508 can comprise MOSFETs. In this arrangement, a source 510 of the third cascode device 506 can be connected to a drain 512 of the third current source 502, and a source 514 of the fourth cascode device 508 can be connected to a drain 516 of the fourth current source 504.

A capacitor 518 can be connected between the sources 510, 514 of the third and fourth cascode devices 506, 508, respectively. The capacitor 518 and cascode devices 506, 508 can form a differential amplifier that provides positive feedback for the LNA 500, which can improve the frequency response of the LNA 500. For instance, a capacitance of 12 fF can help the LNA 500 to achieve a linear frequency response well beyond 1 GHz.

The LNA 500 also can include a first input resistor 520 and a second input resistor 522. For example, the resistors 520, 522 can be connected in series and disposed between a gate 528 of a first input MOSFET 530 and a gate 532 of a second input MOSFET 534. In addition, a first input capacitor 536 can be connected between the gate 528 of the first input MOSFET 530 and a source 538 of the second input MOSFET 534, and a second input capacitor 540 can be connected between the gate 532 of the second input MOSFET 534 and a source 542 of the first input MOSFET 530. The input resistors 520, 522 and input capacitors 536, 540, in combination with the input MOSFETs 530, 534, can increase the gain of input devices. Accordingly, smaller input devices can be used for a given gain, thus reducing the parasitic capacitance associated with these devices and improving the high frequency response. In addition, the input capacitors 536, 540 provide a level of rejection for common mode noise and distortion.

In addition to the load isolation devices 152, 154, the output stage 544 can include a plurality of cascode devices 156, 158, 160, 162, 164, 166. This arrangement can increase the output impedance of the output stage 544 and provide greater operational linearity in comparison to cascode devices 153, 155 of the output stage 150 in FIG. 1, thereby improving the frequency response of the output stage 544.

The terms “a” and “an,” as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language).

The term connected, as used herein, is defined as being connected via a continuous electrically conductive path (i.e. a path that, relative to the devices being connected, has low DC resistance). The term “coupled”, as used herein, is defined as communicatively linked, either by direct electrical connection or by any other communication link. For example, devices which are coupled may be communicatively linked through an intended communication channel or pathway, linked via intended capacitive coupling, inductive coupling, RF coupling, an impedance isolation system, an impedance changing system, or communicatively linked in any other suitable manner.

The term resistor, as used herein, is defined as one or more components having an associated resistance value (e.g. a resistor may be formed from a plurality of resistive components connected in series and/or in parallel). Similarly, the term capacitor, as used herein, is defined as one or more components having an associated capacitance value (e.g. a capacitor may be formed from a plurality of capacitive components connected in series and/or in parallel).

This invention can be embodied in other forms without departing from the spirit or essential attributes thereof. Accordingly, reference should be made to the following claims, rather than to the foregoing specification, as indicating the scope of the invention.

What is claimed is:

1. A wideband low noise RF amplifier (LNA) comprising:
an inductorless internal amplifier load comprising:
a first resistor coupled to an external load or a load isolation stage;
a first current source connected in parallel to the first resistor to provide at least a first portion of load current;
a second resistor coupled to the external load or the load isolation stage; and
a second current source connected in parallel to the second resistor to provide at least a second portion of load current.

2. The wideband LNA of claim 1, wherein the first current source comprises a first MOSFET and the second current source comprises a second MOSFET.

3. The wideband LNA of claim 2, wherein a drain of the first MOSFET is connected to a first terminal of the first resistor, a source of the first MOSFET is connected to a second terminal of the first resistor; a drain of the second MOSFET is connected to a first terminal of the second resistor, and a source of the second MOSFET is connected to a second terminal of the second resistor.

4. The wideband LNA of claim 2, wherein a gate of the first MOSFET is connected to a gate of the second MOSFET.

5. The wideband LNA of claim 2, further comprising a biasing system that biases the first and second MOSFETs, the biasing system comprising:
a third resistor having a first terminal connected to a gate of the first MOSFET, and the third resistor having a second terminal connected to a drain of the first MOSFET; and
a fourth resistor having a first terminal electrically connected to a gate of the second MOSFET, and the fourth resistor having a second terminal connected to a drain of the second MOSFET.

6. The wideband LNA of claim 1, further comprising a load isolation stage that isolates the internal amplifier load from an external load.

7. The wideband LNA of claim 6, wherein the load isolation stage comprises a first load isolation device and a second load isolation device.

8. The wideband LNA of claim 7, wherein the first and second load isolation devices are MOSFETs.

9. The wideband LNA of claim 8, wherein a gate of the first load isolation device is connected to a first terminal of the first resistor, and a gate of the second load isolation device is connected to a first terminal of the second resistor.

10. The wideband LNA of claim 2, further comprising:
a first cascode device connected to the first resistor; and
a second cascode device connected to the second resistor.

11. The wideband LNA of claim 10, wherein the first and second cascode devices are MOSFETs.

12. The wideband LNA of claim 11, further comprising:
a first automatic gain control (AGC) device connected to the first cascode device; and
a second AGC device connected to the second cascode device.

13. The wideband LNA of claim 12, wherein the first and second AGC devices are MOSFETs.

14. The wideband LNA of claim 11, further comprising a capacitor connected between a source of the first cascode device and a source of the second cascode device.

15. The wideband LNA of claim 14, wherein the capacitor, the first cascode device, and the second cascode device form a differential amplifier.

16. The wideband LNA of claim 15, wherein the differential amplifier provides positive feedback for RF signals processed by the LNA.

17. The wideband LNA of claim 1, wherein the first portion of load current is generated on a first line of a balanced line and the second portion of load current is generated on a second line of the balanced line.

18. The wideband LNA of claim 17, wherein the internal amplifier load further comprises:
a third current source connected to the first current source to provide a third portion of current, the third portion of current being generated on the first line; and
a fourth current source connected to the second current source to provide a fourth portion of current, the fourth portion of current being generated on the second line.

19. The wideband LNA of claim 18, wherein the third current source comprises a third MOSFET and the fourth current source comprises a fourth MOSFET.

20. The wideband LNA of claim 1, wherein the LNA comprises a differential balanced line input.
